(19) United States
(12) Patent Application Publication
(10) Pub. No.: US 2026/0023118 A1
(43) Pub. Date: Jan. 22, 2026

(54) APPARATUS AND METHOD FOR TESTING WHETHER AN OUTPUT OF A CONTROLLER CAN BE SWITCHED OFF

(71) Applicant: WAGO Verwaltungsgesellschaft mbH, Minden (DE)

(72) Inventors: Christian VOSS, Minden (DE); Torsten MEYER, Penningsehl (DE)

(73) Assignee: WAGO Verwaltungsgesellschaft mbH, Minden (DE)

(21) Appl. No.: 19/271,250

(22) Filed: Jul. 16, 2025

(30) Foreign Application Priority Data
Jul. 17, 2024 (DE) 10 2024 120 217.3

(51) Int. Cl. G01R 31/327

(52) U.S. Cl. CPC G01R 31/327

(57) ABSTRACT

An apparatus and a method for testing whether an output can be switched off during a test routine. A switch is opened which connects a voltage or current source to the output for a first time period. During at least a part of the first time period, a voltage or a current output is measured and the switch is closed at the end of the first time period. The voltage or current curve measured during the first time period is assessed based on one or more predetermined criteria which serve as an indication of whether the output can be switched off and, if the one or more predetermined criteria are met, the test routine is terminated and, if the one or more predetermined criteria are not met, the test routine is continued by opening the switch for a second time period which is longer than the first time period.

This nonprovisional application claims priority under 35 U.S.C. § 119 (a) to German Patent Application No. 10 2024 120 217.3, which was filed in Germany on Jul. 17, 2024, and which is herein incorporated by reference.

### FIELD OF THE INVENTION

The present invention relates to an apparatus and a method for testing whether an output can be switched off. In particular, the present invention relates to an apparatus and a method for testing a switch, which connects the output to a voltage or current source when closed, with regard to whether the switch can be opened to turn the output off.

### DESCRIPTION OF THE BACKGROUND ART

To ensure that an installation controlled by an apparatus can be transitioned into a safe state at any time, it may be necessary to continuously test whether the outputs of the apparatus can be switched off during operation. For example, the outputs may be checked for their ability to be switched off using so-called test pulses. There, the outputs are switched off (simultaneously or sequentially) for a short time period and the signal level at the output is measured. If the electrical voltage at the load drops to a previously defined threshold during the test pulse, this may be interpreted as an indication that the output can be switched off.

Depending on the application, loads with very diverse properties may be connected to outputs. Accordingly, a commissioning engineer may be burdened with the need to determine and set a suitable test pulse duration.

### SUMMARY OF THE INVENTION

It is therefore an object of the invention to provide a method for testing whether an output of a controller can be switched off.

In an example, the method may comprise: determining that a time has come to perform a test routine, opening a switch connecting a voltage or current source to the output for a first time period, measuring, for at least a part of the first time period, a voltage or a current output at the output, closing the switch at the end of the first time period, and assessing the voltage or current curve measured during the first time period based on one or more predetermined criteria which serve as an indication that the output can be switched off. If the one or more predetermined criteria are met, the method may further comprise terminating the test routine.

If the one or more predetermined criteria are not met, the method may comprise continuing the test routine by opening the switch for a second time period which is longer than the first time period, measuring, for at least a part of the second time period, a voltage or a current output at the output, and assessing the voltage or current curve measured during the second time period based on the one or more predetermined criteria which serve as an indication that the output can be switched off.

In this regard, the term “output”, may refer to an electrical connection via which a voltage or a current can be output, wherein the voltage level and/or the current intensity is controlled by an apparatus which may be a controller. Furthermore, the term “controller” may refer to an apparatus which derives the voltage level and/or the current intensity from signals supplied to the controller (e.g., sensor signals). Furthermore, the term “switch off”, may refer to the reduction of the voltage level and/or the current intensity to zero.

Moreover, the term “test routine” may refer to a procedure comprising several consecutive steps, the procedure aiming at determining whether one or more components of the controller are functioning correctly. Furthermore, the term “voltage or current source”, may refer to a source of electrical energy which is configured to provide a constant voltage or a constant current. In addition, the terms “closing the switch” and “opening the switch”, may refer to actually (or attemptedly) establishing an electrical connection between, or disconnecting, electrical conductors connected to the poles of the switch.

The method may further comprise determining that a time has come to perform the test routine again, opening the switch for the first time period, measuring, for at least a part of the first time period, a voltage or a current output at the output, closing the switch at the end of the first time period, and assessing the voltage or current curve measured during the first time period based on the one or more predetermined criteria. If the one or more predetermined criteria are met, the method may further comprise terminating the test routine.

If the one or more predetermined criteria are not met, the method may further comprise continuing the test routine by opening the switch for a second time period which is longer than the first time period, measuring, for at least a part of the second time period, a voltage or a current output at the output, and assessing the voltage or current curve measured during the second time period based on the one or more predetermined criteria which serve as an indication that the output can be switched off.

The test routine may be continued with increasing time periods until the one or more predetermined criteria are met or a maximum time period is reached.

If the maximum time period has been reached and the one or more predetermined criteria are not met, the method may further comprise signaling that the one or more predetermined criteria are not met. Signaling may include sending a warning message and/or issuing an acoustic and/or optical warning signal.

The method may further comprise transitioning an installation, which is at least partially controlled via the voltage or the current output at the output, into a safe state. If, for example, an actuator is connected to the output and the actuator cannot be deactivated because the output cannot be switched off, the parts of the installation that can be influenced by the actuator may be shut down or deactivated. In addition or alternatively, the power supply to the controller or the installation may be interrupted so that the actuator is de-energized regardless of whether the switch is open or closed.

The voltage or current output at the output may control an actuator of the installation. The actuator may, for example, be a motor that is controlled by the voltage or current output at the output.

According to a second aspect, an apparatus may comprise an output, a switch which is configured to connect the output to a voltage or current source when closed and to disconnect the output from the voltage or current source when open, and a circuit which is configured to carry out test routines at specific times with regard to whether the output of the apparatus can be switched off, wherein during a test routine the switch is temporarily opened for increasing time periods until either a maximum period of time is reached or a change in the voltage or the current output at the output caused by opening the switch meets one or more predetermined criteria which are interpreted as an indication that the output can be switched off.

In this regard, the term “circuit”, may refer an arrangement of electrical and/or electronic components which form a functional unit. The circuit may, for example, be a microcontroller.

The circuit may be further configured, if the maximum time period is reached and the change in the voltage or the current output at the output caused by the opening of the switch does not meet the one or more predetermined criteria, to output a signal indicating that by (attemptedly) opening the switch the output cannot be switched off as expected.

The apparatus may further comprise a further switch which is configured to disconnect the output from the voltage or current source when open. The circuit may be further configured, if the maximum time period is reached and the one or more predetermined criteria are not met, to permanently open the further switch to switch off the output. For example, the switches may be connected in series.

During the test routine, both switches may be tested (for instance one after the other). To this end, the additional switch (with the switch closed) may also be temporarily opened during the test routine for increasing time periods until either a maximum time period is reached or a change in the voltage or current output at the output caused by the opening of the additional switch meets one or more predetermined criteria which are interpreted as an indication that the output can be switched off.

According to a third aspect, an installation may comprise the apparatus and an actuator, wherein the actuator is controlled by the voltage or current output at the output.

The circuit may be configured to transition the system into a safe state if the maximum time period is reached and the one or more predetermined criteria are not met.

Furthermore, it is understood that the features described in connection with the apparatus/installation may also be features of the method, which may be directed at using the apparatus/installation and vice versa.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a block diagram of an installation comprising an apparatus and a load connected to the apparatus;

FIG. 2 illustrates a first exemplary flow of the test routine based on input and output voltages and the state of the switch;

FIG. 3 illustrates a second exemplary flow of the test routine based on input and output voltages and the state of the switch;

FIG. 4 illustrates a first possible modification of the apparatus shown in FIG. 1;

FIG. 5 illustrates a second possible modification of the apparatus shown in FIG. 1;

FIG. 6 illustrates a third possible modification of the apparatus shown in FIG. 1; and

FIG. 7 shows a flowchart of the test routine.

### DETAILED DESCRIPTION

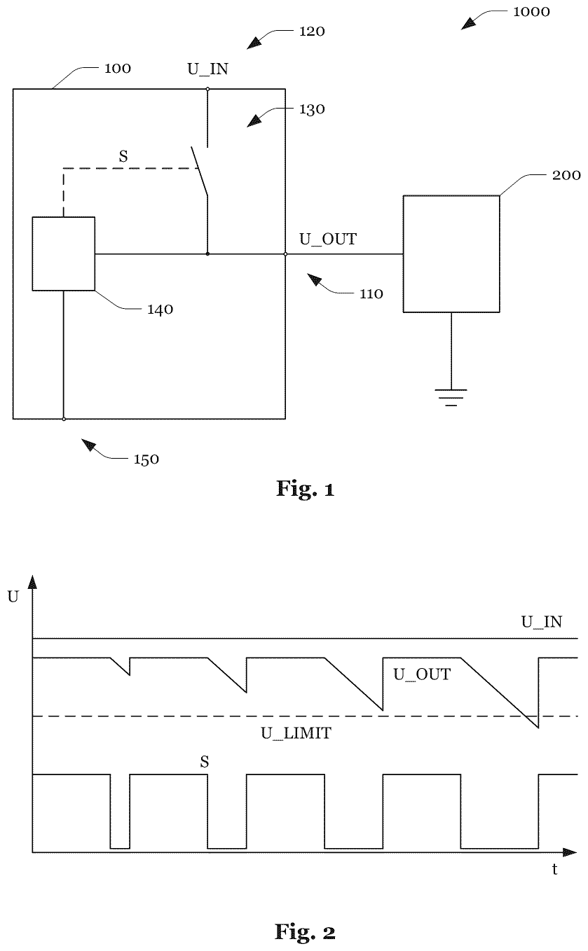

FIG. 1 shows an installation 1000 with an apparatus 100 that may be a controller, and a load 200 that may be an actuator, wherein the load 200 is connected to an output 110 of the apparatus 100. The apparatus 100 comprises a first input 120 which is connected to a voltage source. The voltage source supplies the apparatus 100 with a constant voltage U_IN. The apparatus 100 further comprises a switch 130 via which the input 120 is connected to the output 110. If the switch 130 is closed, the apparatus 100 outputs an output voltage U_OUT at the output 110 which corresponds to, or is derived from, the input voltage U_IN. The apparatus 100 further comprises a circuit 140 which controls the switch 130 and measures the voltage U_OUT output at the output 110 via a readback line. The circuit 140 further reads a signal via a second input 150 which specifies, or from which the circuit 140 derives, when the switch 130 should be closed or opened during normal operation. For example, the input 150 may be connected to a button and the voltage supply of the load 200 may be controlled by actuating the button, or the input 150 may be connected to a sensor and the circuit 140 may derive from a sensor signal whether or when the load 200 is to be supplied with the output voltage U_OUT.

To test the functionality of the switch 130 when the switch 130 is closed without interrupting the voltage supply to the load 200 for too long, the circuit 140 opens the switch 130 by reducing the control voltage S applied to a control input of the switch 130 initially for a short period of time (e.g., 1 ms) as schematically illustrated in FIG. 2. Within this time period, the output voltage U_OUT hardly drops. Because the output voltage U_OUT does not fall below the threshold value U_LIMIT, the circuit 140 considers the first test pulse to have failed. This triggers a second test pulse with a longer duration (e.g. 2 ms) which, however, also fails. Only with the fourth test pulse which has a significantly increased duration (e.g. 10 ms), the output voltage U_OUT falls below the threshold voltage U_LIMIT, which is considered an indication that the output 110 can be switched off. However, due to the load 200 being a capacitive load 200, the voltage U_OUT applied to the load 200 may not drop significantly during the relatively short test pulses, so that the operation of the load 200 may not be significantly disturbed by the test pulses.

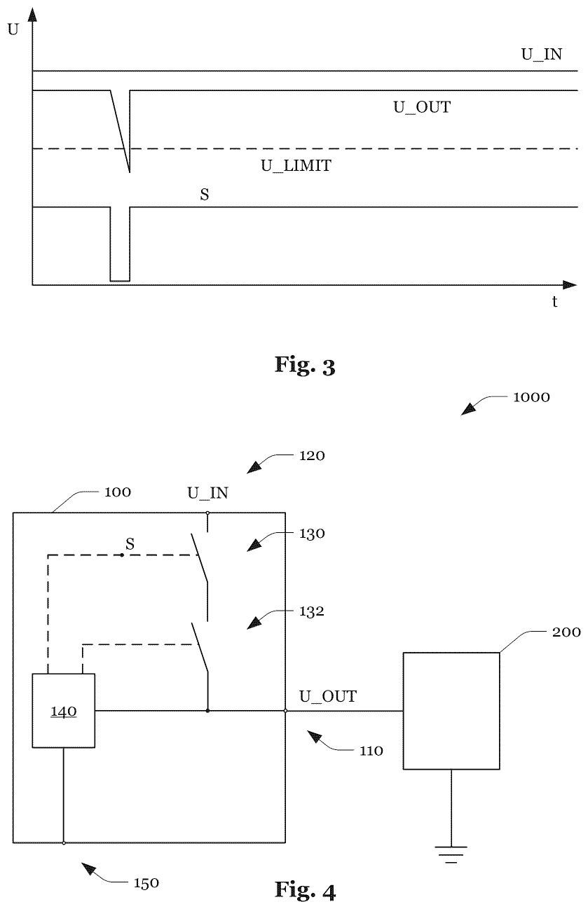

FIG. 3 shows the flow of the test routine in the case of a resistive load 200. In this case, the output voltage U_OUT drops significantly faster which results in the output voltage U_OUT falling below the threshold value U_LIMIT already in response to the first test pulse, so that the test routine can be terminated after the first test pulse. This procedure is advantageous over an adaptive test pulse which is terminated when the output voltage U_OUT falls below the threshold value U_LIMIT, in that a test pulse can be shorter than the time required to switch the output 110 back on if the test is passed. In order to exclude possible misinterpretations due to externally induced interference, the test may only be considered successful if the test can be successfully repeated with a test pulse of the same length. The number of successful repetitions required may be set absolutely, e.g. 3 successful repetitions in a certain period of time, or relatively, e.g. 50% of the repetitions performed in the certain period of time.

As shown in FIG. 4, the apparatus 100 may comprise another switch 132 between the input 120 and the output 110, which is connected in series with switch 130. Both switches 130 and 132 may be tested independently of each other, e.g., at different times, with regard to their switchability. If the switchability test shows that one of the switches 130 or 132 is not switchable, the output 110 may still be switched off by opening the switchable switch 130 or 132. Alternatively or additionally, the apparatus 100 may signal to a higher-level control unit that one of the switches 130 or 132 has failed. In response, the higher-level control unit may transition the installation 1000 which includes the device 100 and the load 200 and which is controlled by the higher-level control unit, into a safe state and/or shut the installation 1000 down and/or signal the apparatus 100 to switch the output 110 off and/or disconnect the apparatus 100 from the power supply.

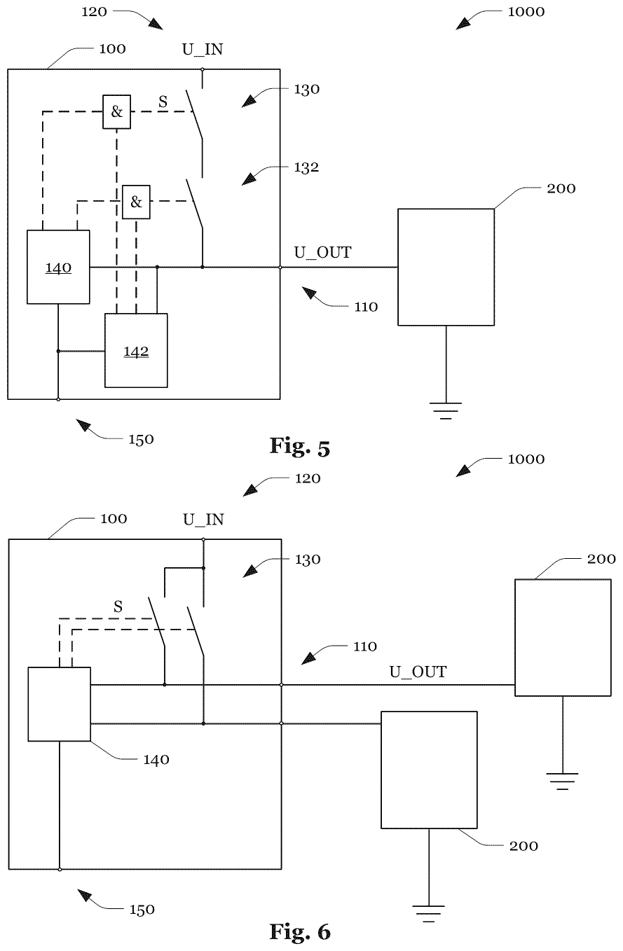

As shown in FIG. 5, the apparatus 100 may include two circuits 140 and 142 which monitor each other. The control voltage S applied to the control input of the switch 130 may be derived by means of a logic element from control voltages output by both circuits 140 and 142, so that each of the circuits 140 and 142 can open the switch 130. The same may be provided for with respect to the second switch 132. As shown in FIG. 6, the apparatus 100 may comprise two channels. In this regard, it is noted that the apparatus 100 shown in FIG. 6 may also be adapted according to the modifications shown in FIG. 4 and FIG. 5.

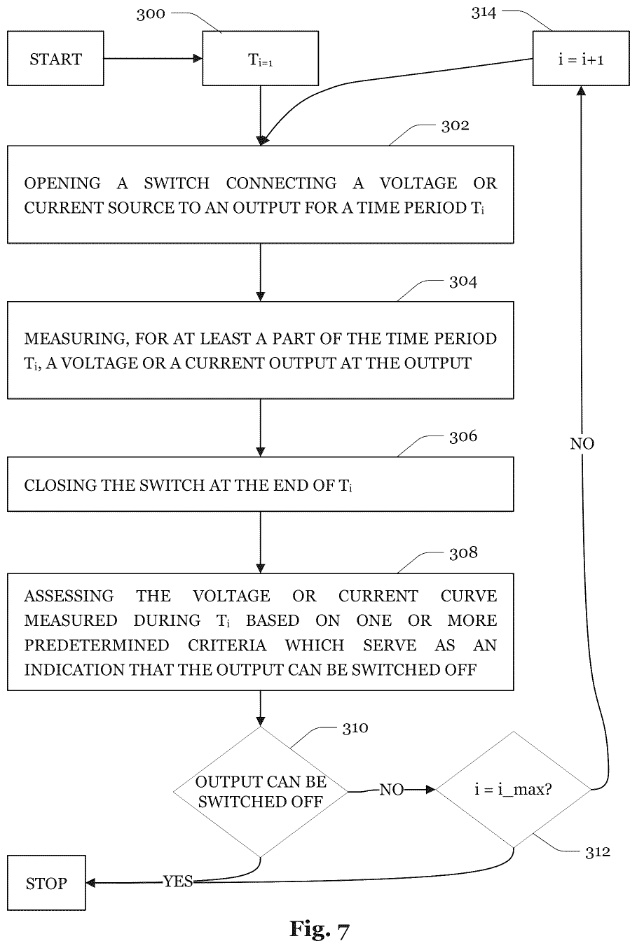

FIG. 7 shows a flowchart of a method for testing whether the output 110 can be switched off. During each test, a test pulse with the shortest possible duration T₁ is initially used. To this end, after setting the time period 300, the switch 130, which connects the voltage or current source to the output 110, is opened for the time period T₁. After measuring 304 the voltage U_OUT output at the output 110 or the current output at the output 110, the switch 130 is closed 306. After assessing 308 the voltage or current curve measured during the time period T₁ based on one or more predetermined criteria, which serve as an indication that the output 110 can be switched off, the decision 310 is made as to whether the test can be considered successful.

If the load 200 has a sufficiently fast characteristic and the test pulse T₁ can be considered successful by reading back the output voltage U_OUT, the test routine is terminated. If the load 200 is too slow for the short test pulse T₁ and the decision 312 has been made that a maximum number iₘₐₓ of test pulses has not yet been reached in this test routine, the time duration is increased 314 and the next longer test pulse duration T₂ is tried. The test routine continues until a test pulse is successful or the longest possible test pulse duration T₁_max is reached. If the test pulse with the longest duration fails, the test routine is considered to have failed.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for testing whether an output of a controller can be switched off, the method comprising:
determining that a time has come to perform a test routine;
opening a switch connecting a voltage or current source to the output for a first time period;
measuring, for at least a part of the first time period, a voltage or a current output at the output;
closing the switch at an end of the first time period;
assessing the voltage or current curve measured during the first time period based on one or more predetermined criteria that serve as an indication that the output can be switched off; and
terminating the test routinge if the one or more predetermined criteria are met and if the one or more predetermined criteria are not met, continuing the test routine by:
opening the switch for a second time period which is longer than the first time period;
measuring, for at least a part of the second time period, a voltage or a current output at the output; and
assessing the voltage or current curve measured during the second time period based on the one or more predetermined criteria which serve as an indication that the output can be switched off.

2. The method of claim 1, further comprising:
determining that a time has come to perform the test routine again;
opening the switch for the first time period;
measuring, for at least a part of the first time period, a voltage or a current output at the output;
closing the switch at the end of the first time period;
assessing the voltage or current curve measured during the first time period based on the one or more predetermined criteria;
terminating the test routine if the one or more predetermined criteria are met, and if the one or more predetermined criteria are not met, continuing the test routine by:
opening the switch for a second time period which is longer than the first time period;
measuring, for at least a part of the second time period, a voltage or a current output at the output; and
assessing the voltage or current curve measured during the second time period based on the one or more predetermined criteria.

3. The method of claim 1, wherein the test routine is continued with increasing time periods until the one or more predetermined criteria are met or a maximum time period is reached, and wherein, if the maximum time period has been reached and the one or more predetermined criteria are not met, the method further comprises:
signaling that the one or more predetermined criteria are not met.

4. The method of claim 3, further comprising:
transitioning an installation, which is at least partially controlled via the voltage or the current output at the output, into a safe state.

5. The method of claim 4, wherein the voltage or the current output at the output controls an actuator of the installation.

6. An apparatus comprising:
an output;
a switch configured to connect the output to a voltage or current source when closed and to disconnect the output from the voltage or current source when open; and
a circuit configured to carry out test routines at specific times with regard to whether the output of the apparatus can be switched off,
wherein during a test routine the switch is temporarily opened for increasing time periods until either a maximum time period is reached or a change in the voltage or the current output at the output caused by opening the switch meets one or more predetermined criteria which are interpreted as an indication that the output can be switched off.

7. The apparatus of claim 6, wherein the circuit is further configured, if the maximum time period is reached and the change in the voltage or the current output at the output caused by the opening of the switch does not meet the one or more predetermined criteria, to output a signal indicating that the output cannot be switched off as expected by opening the switch.

8. The apparatus of claim 6, further comprising:
a second switch configured to disconnect the output from the voltage or current source when open,
wherein the circuit is further configured, if the maximum time period is reached and the one or more predetermined criteria are not met, to permanently open the second switch to switch off the output.

9. An installation comprising:
the apparatus of claim 6; and
an actuator, wherein the actuator is controlled by the voltage or the current output at the output.

10. The installation according to claim 9, wherein the circuit is configured to transition the installation into a safe state if the maximum time period is reached and the one or more predetermined criteria are not met.
